(19) United States
(12) Patent Application Publication
(10) Pub. No.: US 2013/0077423 A1
(43) Pub. Date: Mar. 28, 2013

(54) REFRESH METHOD AND APPARATUS FOR A SEMICONDUCTOR MEMORY DEVICE

(71) Applicant: Byeong Cheol LEE, Seoul (KR)

(72) Inventor: Byeong Cheol LEE, Seoul (KR)

(73) Assignee: HYNIX SEMICONDUCTOR INC., Icheon-si (KR)

(21) Appl. No.: 13/336,827

(22) Filed: Dec. 23, 2011

(30) Foreign Application Priority Data
Sep. 23, 2011 (KR) 10-2011-0096453

(51) Int. Cl. G11C 11/402; G11C 7/12; G11C 7/06

(52) U.S. Cl. 365/203; 365/207

(57) ABSTRACT

A semiconductor memory device includes a bit line sense amplifier configured to sense and amplify data of a first bit line coupled to a first memory cell of a first cell block when a refresh operation is performed on the first cell block, and sense and amplify data of a second bit line coupled to a second memory cell of a second cell block when a refresh operation is performed on the second cell block. A first switch may be configured to block coupling between the first bit line and the bit line sense amplifier when a refresh operation is performed on the second cell block and a second switch may be configured to block coupling between the second bit line and the bit line sense amplifier when a refresh operation is performed on the first cell block.

### CROSS-REFERENCES TO RELATED APPLICATIONS

The present application claims priority under 35 U.S.C 119(a) to Korean Application No. 10-2011-0096453 filed on Sep. 23, 2011 in the Korean intellectual property Office, which is incorporated by reference in its entirety.

### BACKGROUND

DRAM (Dynamic Random Access Memory) loses data stored in its memory cells as time elapses, unlike SRAM (Static Random Access Memory) or Flash memory. In order to prevent the loss of data, DRAM performs an operation of rewriting the information stored in the memory cell within a retention time. The operation is referred to as refresh. The retention time refers to a time during which data may be maintained in a memory cell without refresh after the data is written into the memory cell.

The refresh is performed by enabling a word line at least once within a retention time of each memory cell within a bank and sensing and amplifying data. The operation in which data are sensed and amplified during the refresh will be described in more detail as follows.

When a bit line precharged with a bit line precharge voltage is coupled to a memory cell by an enabled word line in a standby state, a voltage level is increased or decreased by charge sharing. That is, when data stored in the memory cell is at a high level, the voltage level of the bit line increases, and when the data is at a low level, the voltage level of the bit line decreases.

After the data stored in the memory cell is loaded into the bit line, a bit line sense amplifier coupled to the bit line and a bit line bar senses and amplifies the data loaded in the bit line. That is, when the voltage level of the bit line is higher than that of the bit line bar, the bit line sense amplifier charges the bit line with a core voltage level, and discharges the bit line bar to a ground voltage level. When the voltage level of the bit line is lower than the voltage level of the bit line bar, the bit line sense amplifier discharges the bit line to the ground voltage level, and charges the bit line bar with the core voltage level.

As such, when refresh is performed, data stored in all memory cells included in the memory semiconductor device should be sensed and amplified. In order to sense and amplify the data, the bit line and the bit line bar should be charge and discharged by the bit line sense amplifier.

As semiconductor memory devices become ever more highly integrated, the number of charging and discharging operations of the bit line sense amplifier for the bit line and the bit line bar during refresh increases by geometric progression. Therefore, current consumption also increases significantly. Furthermore, current consumption required for auto refresh comprises 70% or more of the current consumption required for charging and discharging the bit line and the bit line bar, and current consumption required for self refresh comprises 20% or more of the current consumption required for charging and discharging the bit line and the bit line bar.

### SUMMARY

An embodiment of the present invention relates to a semiconductor memory device capable of reducing a current required for charging and discharging a bit line, thereby reducing a current required during refresh.

In one embodiment, a semiconductor memory device includes a bit line sense amplifier configured to sense and amplify data of a first bit line coupled to a first memory cell of a first cell block when a refresh operation is performed on the first cell block, and sense and amplify data of a second bit line coupled to a second memory cell of a second cell block when a refresh operation is performed on the second cell block. A first switch may be configured to block coupling between the first bit line and the bit line sense amplifier when a refresh operation is performed on the second cell block, and a second switch may be configured to block coupling between the second bit line and the bit line sense amplifier when a refresh operation is performed on the first cell block.

In another embodiment, a semiconductor memory device includes a bit line sense amplifier coupled to a bit line and a bit line bar and configured to sense and amplify data of the bit line when a refresh operation is performed on a cell block. A switch may be configured to block a coupling between the bit line bar and the bit line sense amplifier when a refresh operation is performed on the cell block.

In another embodiment, a method may comprise coupling a bit line sense amplifier to a bit line and a bit line bar where the bit line sense amplifier is configured to sense and amplify data of the bit line when a refresh operation is performed on a cell block, and electrically decoupling with a switching device the bit line bar from the bit line sense amplifier when a refresh operation is performed on the cell block.

### BRIEF DESCRIPTION OF THE DRAWINGS

The above and other aspects, features, and advantages will be more clearly understood from the following detailed description taken in conjunction with the accompanying drawings:

FIG. 1 illustrates an exemplary configuration of a semiconductor memory device in accordance with an embodiment of the present invention;

FIG. 2 is a circuit diagram of an exemplary first switching signal generation unit included in the semiconductor memory device of FIG. 1;

FIG. 3 is a circuit diagram of an exemplary second switching signal generation unit included in the semiconductor memory device of FIG. 1; and

FIG. 4 illustrates an exemplary configuration of a semiconductor memory device in accordance with another embodiment of the present invention.

### DESCRIPTION OF SPECIFIC EMBODIMENTS

Embodiments of the present invention will be described with reference to accompanying drawings. However, the embodiments are for illustrative purposes only and are not intended to limit the scope of the invention.

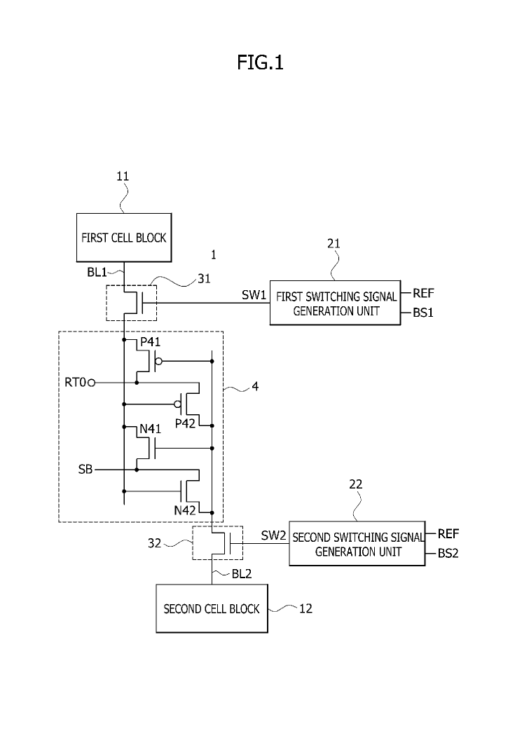

FIG. 1 illustrates an exemplary configuration of a semiconductor memory device in accordance with an embodiment of the present invention.

Referring to FIG. 1, the semiconductor memory device in accordance with an embodiment of the present invention includes a first cell block 11, a second cell block 12, a first switching signal generation unit 21, a second switching signal generation unit 22, a first switch 31, and a second switch 32. The first cell block 11 is coupled to a first bit line BL1, and the second cell block 12 is coupled to a second bit line BL2. The first switching signal generation unit 21 is configured to generate a first switching signal SW1 in response to a refresh signal REF and a first bank select signal BS1. The second switching signal generation unit 22 is configured to generate a second switching signal SW2 in response to the refresh signal REF and a second bank select signal BS2. The first switch 31 is configured to control coupling between the first bit line BL1 and a bit line sense amplifier 4 in response to the first switching signal SW1. The second switch 32 is configured to control coupling between the second bit line BL2 and the bit line sense amplifier 4 in response to the second switching signal SW2. The refresh signal REF is asserted to a high level when a refresh operation is performed on the first or second cell block 11 or 12. The first bank select signal BS1 is asserted to a high level when a refresh operation is performed on the first cell block 11, and the second bank select signal BS2 is asserted to a high level when a refresh operation is performed on the second cell block 12.

The bit line sense amplifier 4 includes a PMOS transistor P41, a PMOS transistor P42, an NMOS transistor N41, and an NMOS transistor N42. The PMOS transistor P41 is configured to charge the first bit line BL1 with a core voltage VCORE supplied through a first power line RTO in response to data of the second bit line BL2. The PMOS transistor P42 is configured to charge the second bit line BL2 with the core voltage VCORE supplied through the first power line RTO in response to the data of the first bit line BL1. The NMOS transistor N41 is configured to discharge the first bit line BL1 to a ground voltage VSS supplied through a second power line SB in response to data of the second bit line BL2. The NMOS transistor N42 is configured to discharge the second bit line BL2 to the ground voltage VSS supplied through the second power line SB in response to the data of the second bit line BL2.

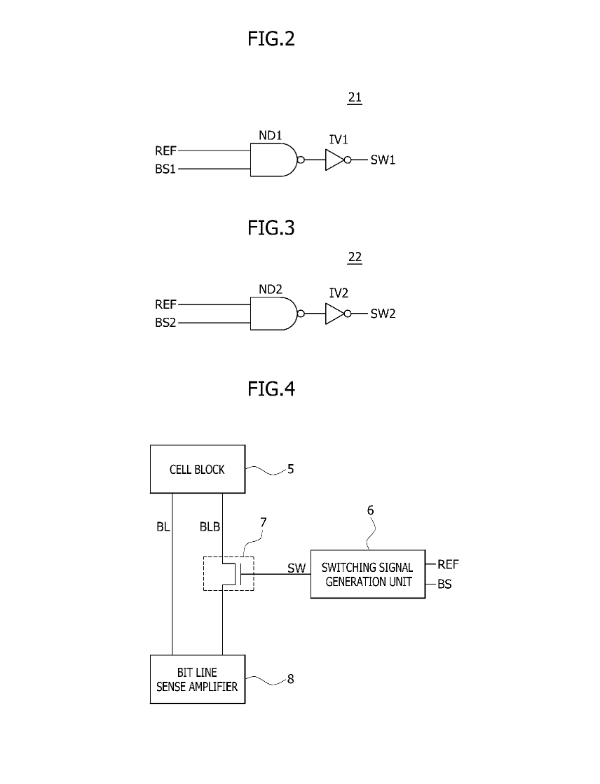

Referring to FIG. 2, the first switching signal generation unit 21 includes a NAND gate ND1 and an inverter IV1. The NAND gate ND1 is configured to perform a NAND operation on the first bank select signal BS1 and the refresh signal REF. The inverter IV1 is configured to invert and buffer an output signal of the NAND gate ND1 and output the buffered signal as the first switching signal SW1. When a refresh operation is performed on the first cell block 11, the first switching signal generation unit 21 generates the first switching signal SW1 at a high level to couple the first bit line BL1 and the bit line sense amplifier 4. Furthermore, when a refresh operation is performed on the second cell block 12, the first switching signal generation unit 21 generates the first switching signal SW1 at a low level to block the coupling between the first bit line BL1 and the bit line sense amplifier 4. When a refresh operation is not performed on the first or second cell block 11 or 12, the first switching generation unit 21 generates the first switching signal SW1 at a low level.

Referring to FIG. 3, the second switching signal generation unit 22 includes a NAND gate ND2 and an inverter IV2. The NAND gate ND2 is configured to perform a NAND operation on the second bank select signal BS2 and the refresh signal REF. The inverter IV2 is configured to invert and buffer an output signal of the NAND gate ND2 and output the buffered signal as the second switching signal SW2. When a refresh operation is performed on the second cell block 12, the second switching signal generation unit 22 generates the second switching signal SW2 at a high level to couple the second bit line BL2 and the bit line sense amplifier 4. When a refresh operation is performed on the first cell block 11, the second switching signal generation unit 22 generates the second switching signal SW2 at a low level to block the coupling between the second bit line BL2 and the bit line sense amplifier 4. When a refresh operation is not performed on the first or second cell block 11 or 12, the second switching generation unit 22 generates the second switching signal SW2 at a low level.

The refresh operation of the semiconductor memory device configured in such a manner will be described. The following descriptions will be of a case in which a refresh operation is performed on the first cell block 11 and a case in which a refresh operation is performed on the second cell block 12.

First, when a refresh operation is performed on the first cell block 11, the refresh signal REF and the first bank select signal BS1 are asserted to a high level, and the second bank select signal BS2 is deasserted to a low level. The first switching signal SW1 generated by the first switching signal generation unit 21 is at a high level due to the high-level refresh signal REF and the high-level first bank select signal BS1. The second switching signal SW2 generated by the second switching signal generation unit 22 is at a low level due to the high-level refresh signal REF and the low-level second bank select signal BS2. Therefore, the first switch 31 is turned on to couple the first bit line BL1 and the bit line sense amplifier 4, and the second switch 32 is turned off to block the coupling between the second bit line BL2 and the bit line sense amplifier 4.

When a refresh operation is performed on the second cell block 12, the refresh signal REF and the second bank select signal BS2 are asserted to a high level, and the first bank select signal BS1 is deasserted to a low level. The second switching signal SW2 generated by the second switching signal generation unit 22 is at a high level due to the high-level refresh signal REF and the high-level second bank select signal BS2. The first switching signal SW1 generated by the first switching signal generation unit 21 is at a low level due to the high-level refresh signal REF and the low-level bank select signal BS1. Therefore, the first switch 31 is turned off to block the coupling between the first bit line BL1 and the bit line sense amplifier 4, and the second switch 32 is turned on to couple the second bit line BL2 and the bit line sense amplifier 4.

As described above, when a refresh operation is performed on the first cell block 11, the semiconductor memory device in accordance with an embodiment of the present invention blocks the coupling between the second bit line BL2 and the bit line sense amplifier 4 such that the bit line sense amplifier 4 does not charge or discharge the second bit line BL2, thereby reducing current consumption. Meanwhile, when a refresh operation is performed on the second cell block 12, the semiconductor memory device blocks the coupling between the first bit line BL1 and the bit line sense amplifier 4 such that the bit line sense amplifier 4 does not charge or discharge the first bit line BL1, thereby reducing current consumption.

FIG. 4 illustrates the configuration of a semiconductor memory device in accordance with another embodiment of the present invention.

Referring to FIG. 4, the semiconductor memory device in accordance with an embodiment of the present invention includes a cell block 5, a switching signal generation unit 6, and a switch 7. The cell block 5 is coupled to a bit line BL and a bit line bar BLB. The switching signal generation unit 6 is configured to generate a switching signal SW in response to a refresh signal REF and a bank select signal BS. The switch 7 is configured to control coupling between the bit line bar BLB and a bit line sense amplifier 8 in response to the switching signal SW. The refresh signal REF and the bank select signal BS are asserted to a logic high level when a refresh operation is performed on the cell block 5.

When a refresh operation is performed on the cell block 5, the switching signal generation unit 6 generates the switching signal SW deasserted to a logic low level to block the coupling between the bit line bar BLB and the bit line sense amplifier 8.

As described above, when a refresh operation is performed on the cell block 5, the semiconductor memory device in accordance with an embodiment of the present invention blocks the coupling between the bit line bar BLB and the bit line sense amplifier 8 such that the bit line sense amplifier 8 does not charge or discharge the bit line bar BLB, thereby reducing current consumption.

The embodiments of the present invention have been disclosed above for illustrative purposes. Those skilled in the art will appreciate that various modifications, additions, and substitutions are possible, without departing from the scope and spirit of the invention as disclosed in the accompanying claims.

What is claimed is:

1. A semiconductor memory device comprising:
a bit line sense amplifier configured to sense and amplify data of a first bit line coupled to a first memory cell of a first cell block when a refresh operation is performed on the first cell block, and sense and amplify data of a second bit line coupled to a second memory cell of a second cell block when a refresh operation is performed on the second cell block;
a first switch configured to block coupling between the first bit line and the bit line sense amplifier when a refresh operation is performed on the second cell block; and
a second switch configured to block coupling between the second bit line and the bit line sense amplifier when a refresh operation is performed on the first cell block.

2. The semiconductor memory device of claim 1, wherein the bit line sense amplifier charges the first bit line with a first internal voltage of a first power line and discharges the second bit line to a second internal voltage of a second power line when the level of the first bit line is higher level than that of the second bit line.

3. The semiconductor memory device of claim 2, wherein the bit line sense amplifier discharges the first bit line to the second internal voltage of the second power line and charges the second bit line with the first internal voltage of the first power line when the level of the first bit line is higher than that of the second bit line.

4. The semiconductor memory device of claim 3, wherein the first internal voltage comprises a core voltage supplied to a core area, and the second internal voltage comprises a ground voltage.

5. The semiconductor memory device of claim 1, wherein the first switch couples the first bit line and the bit line sense amplifier when a refresh operation is performed on the first cell block.

6. The semiconductor memory device of claim 1, wherein the second switch couples the second bit line and the bit line sense amplifier when a refresh operation is performed on the second cell block.

7. The semiconductor memory device of claim 1, further comprising a first switching signal generation unit configured to generate a first switching signal for controlling the first switch in response to a refresh signal and a first block select signal.

8. The semiconductor memory device of claim 7, further comprising a second switching signal generation unit configured to generate a second switching signal for controlling the second switch in response to the refresh signal and a second block select signal.

9. A semiconductor memory device comprising:
a bit line sense amplifier coupled to a bit line and a bit line bar and configured to sense and amplify data of the bit line when a refresh operation is performed on a cell block; and
a switch configured to block a coupling between the bit line bar and the bit line sense amplifier when a refresh operation is performed on the cell block.

10. The semiconductor memory device of claim 9, wherein the bit line sense amplifier charges the bit line with a first internal voltage of a first power line and discharges the bit line bar to a second internal voltage of a second power line when the level of the bit line is higher level than that of the bit line bar.

11. The semiconductor memory device of claim 10, wherein the bit line sense amplifier discharges the bit line with the second internal voltage of the second power line and charges the bit line bar to the first internal voltage of the first power line when the level of the bit line is lower than that of the bit line bar.

12. The semiconductor memory device of claim 11, wherein the first internal voltage comprises a core voltage supplied to a core area, and the second internal voltage comprises a ground voltage.

13. The semiconductor memory device of claim 9, further comprising a switching signal generation unit configured to generate a switching signal for controlling the switch in response to a refresh signal and a block select signal.

14. A method comprising:
coupling a bit line sense amplifier to a bit line and a bit line bar wherein the bit line sense amplifier is configured to sense and amplify data of the bit line when a refresh operation is performed on a cell block; and
electrically decoupling with a switching device the bit line bar from the bit line sense amplifier when a refresh operation is performed on the cell block.

15. The method of claim 14, wherein the bit line sense amplifier charges the bit line with a first internal voltage of a first power line and discharges the bit line bar to a second internal voltage of a second power line when the level of the bit line is higher level than that of the bit line bar.

16. The method of claim 15, wherein the bit line sense amplifier discharges the bit line with the second internal voltage of the second power line and charges the bit line bar to the first internal voltage of the first power line when the level of the bit line is lower than that of the bit line bar.

17. The method of claim 16, wherein the first internal voltage comprises a core voltage supplied to a core area, and the second internal voltage comprises a ground voltage.

18. The method of claim 14, further comprising generating a switching signal for controlling the switching device in response to a refresh signal and a block select signal.
